(19) United States
(12) Patent Application Publication
(10) Pub. No.: US 2018/0317334 A1
(43) Pub. Date: Nov. 1, 2018

(54) DEVICE FOR CONNECTING ELECTRICAL COMPONENTS WITH A POWER SUPPLY

(71) Applicant: EUGEN FORSCHNER GMBH, Spaichingen (DE)

(72) Inventors: Michael Grotz, Spaichingen (DE); Sven Sautter, Spaichingen (DE); Sebastian MENEGHINI, Spaichingen (DE)

(21) Appl. No.: 15/771,880

(22) PCT Filed: Oct. 24, 2016
(86) PCT No.: PCT/EP2016/075553

§ 371 Date: Apr. 27, 2018

(30) Foreign Application Priority Data
Oct. 28, 2015 (DE) 10 2015 118 443.5
Feb. 18, 2016 (DE) 20 2016 100 869.7
Mar. 23, 2016 (DE) 20 2016 101 623.1

(51) Int. Cl. H05K 7/02; H01R 4/30; H01B 5/02; H01R 11/12; H01R 13/436; H05K 5/02; H02G 3/16; B60R 16/023

(52) U.S. Cl. CPC H05K 7/026; H01R 4/305; H01B 5/02; B60R 16/0238; H01R 13/436; H05K 5/0247; H02G 3/16; H01R 11/12

(57) ABSTRACT

The invention relates to a device (30) for connecting electrical components (20, 22) with a power supply (42). The invention is distinguished in that the device (30) is formed by a three-dimensionally bent wire (32), in which contact regions (36) are formed at least at its ends, preferably also in between. In relation to known devices, which create a connection with power rails or by contact plates, the device according to the invention is producible substantially more simply and cost-effectively and can be three-dimensionally formed nearly arbitrarily.

The invention relates to a device for connecting electrical components with a power supply according to the preamble of claim 1.

Heretofore, power rails made of stamped and bent plates—for example, as known from DE 197 15 824 A1 or from DE 20 2015 103 854 U1 or as shown in FIG. 4—or contact plates having integrated conductor tracks have been used for connecting multiple electronic components arranged in a housing with a power supply. These solutions meet their limits in the case of a complex three-dimensional arrangement of multiple electronic components, since a single power rail can only be deformed to a limited extent and a plate, even in a multilayered, angled embodiment, can only provide contact points in two planes perpendicular to one another, as is apparent, for example, from EP 2 728 982 A1.

The object of the invention is to provide a device for connecting electrical components to a power supply, by means of which nearly arbitrarily complex three-dimensional line paths are achievable.

This object is achieved by a device having the features of claim 1. Advantageous embodiments of the invention are specified in the dependent claims.

The device according to the invention is essentially formed from at least one three-dimensionally formed wire, in which contact regions are formed at least at its ends and preferably at at least one further point. Such a wire can also represent a complex three-dimensional line path having arbitrarily many contact regions. The starting material may be kept in stock cost-effectively and may be cut to size as needed into arbitrary length sections and provided with the required number of contact regions. The contact regions can also be used for the connection with further adjacent three-dimensionally bent wires, so that overall very complexly formed devices can be formed for connecting electrical components.

According to one advantageous embodiment of the invention, it is provided that the wire has a round cross section. This cross section enables an optimum three-dimensional deformability in arbitrary directions and planes.

According to a further advantageous embodiment of the invention, it is provided that the contact regions are formed as flat embossments in the wire.

At least one of the contact regions advantageously has at least one borehole or depression, through which a fastening means for contacting with the power supply or the electrical component or for connection with an adjacent three-dimensionally bent wire can be guided or in which a fastening means for contacting with the power supply or the electrical component or for connection with an adjacent three-dimensionally bent wire can be pressed or screwed.

A further advantageous refinement of the invention provides that a rivet, a press-in spike, a press-in part, or a sleeve can be pressed or at least one screw can be screwed into at least one of the boreholes or depressions. In this way, the contact region is enlarged, which improves the contact to the component, to the power supply, or to an adjacent three-dimensionally bent wire, and ensures a permanent stable contact.

The wire used for the production of the device preferably consists of a metal or a metal alloy having high electrical conductivity.

The contact regions are preferably formed into the wire by pressing, squeezing, and/or stamping, if necessary with the aid of a shaping tool, such as a die or matrix, and the wire is preferably brought into its three-dimensional shape by means of a bending device. It is also possible to firstly apply the desired three-dimensional shape to the wire and subsequently to form the contact regions by laying the corresponding partial regions of the wire in a pressing tool and/or stamping tool.

With the production of a contact region, conductors to be contacted, adjacent three-dimensionally bent wires, or connectors of electrical components can preferably be jointly pressed, printed, stamped, welded, clinched, toxed, crimped, or riveted jointly with the contact region to produce a fixed connection.

A further advantageous embodiment of the invention provides that the contact regions are formed at least at one end of the wire as the contact of a plug. It is particularly advantageous in this case if the contacts, provided with a seal element, are insertable into a receptacle of the plug. In this way, a use in environments and areas of application is also possible in which a high level of leak tightness of the electrical contact in relation to sprayed water or moisture creeping along the conductor is important.

The end of the wire formed as a contact is preferably fixable by means of a locking element on or in a housing of the plug. The locking element can be designed as a mechanical catch device, wherein the locking elements are preferably integrally formed at least partially on the housing.

Another variant is that the locking element is produced by at least partial plastic extrusion coating of the ends of the wire or by a plastic injection into a cavity in the housing after insertion of the ends of the wire, wherein a high level of leak-tightness is also created simultaneously in addition to the mechanical fixing by the plastic extrusion coating or plastic injection.

Exemplary embodiments of the device according to the invention are explained in greater detail hereafter with reference to the drawings. In the figures:

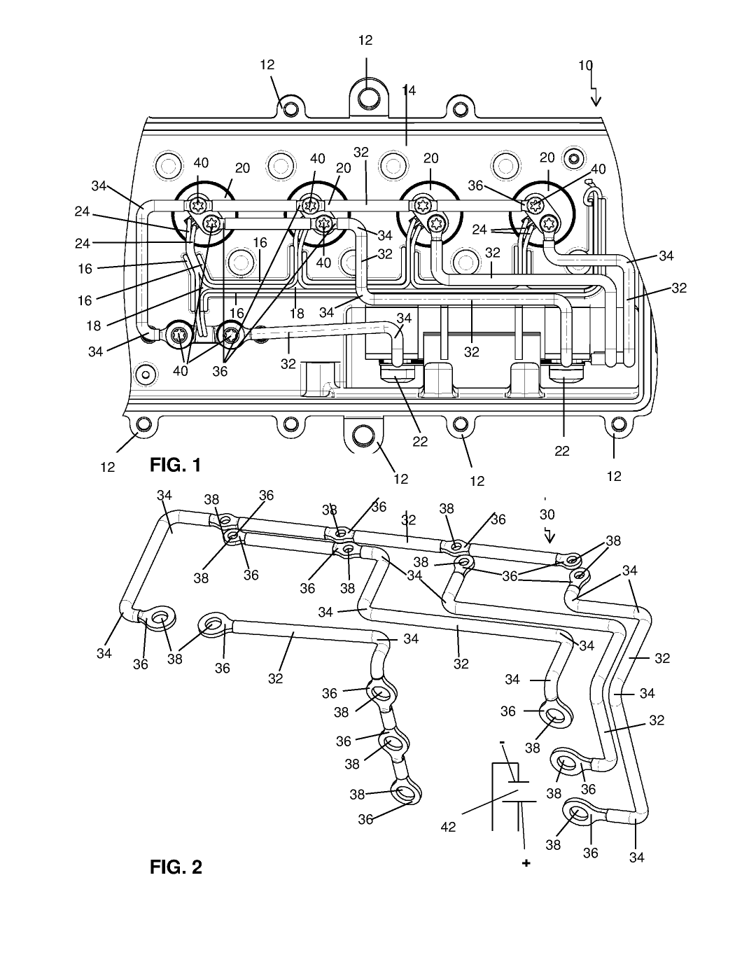

FIG. 1 shows a detail of a housing having multiple electrical components which are connected with a power supply by devices according to the invention;

FIG. 2 shows the devices from FIG. 1 in a separate three-dimensional illustration;

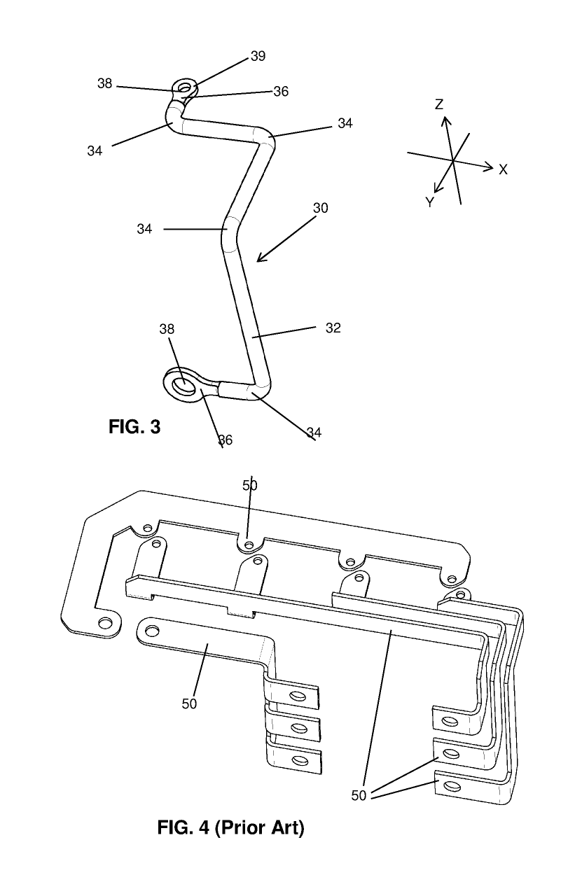

FIG. 3 shows a single device from FIG. 1 in a separate three-dimensional illustration;

FIG. 4 shows conventional power rails (prior art);

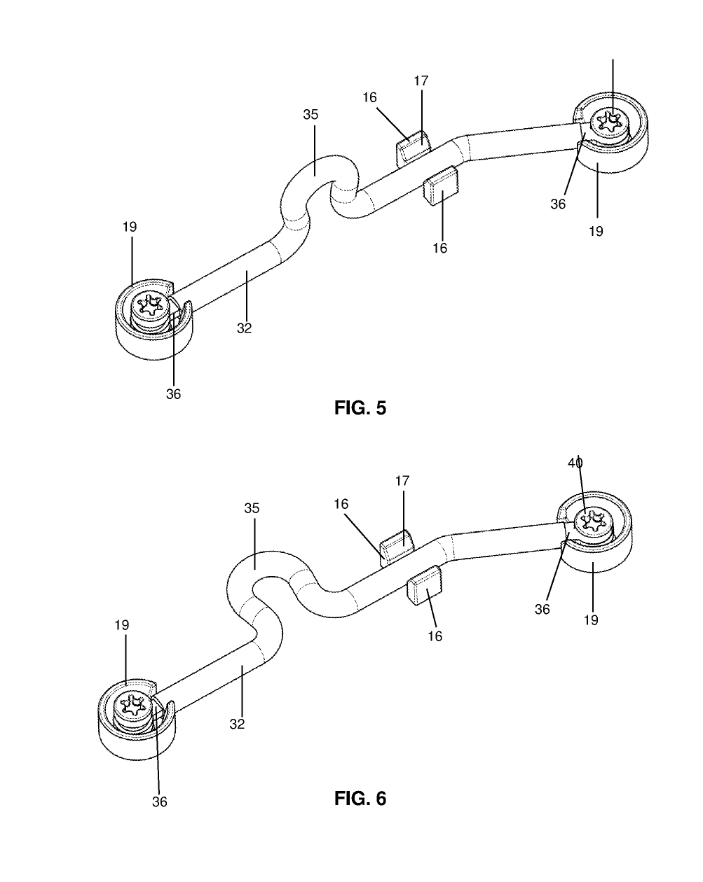

FIG. 5 shows a single device from FIG. 1 in a separate three-dimensional illustration having a loop arranged vertically in relation to the main extension direction and screw connections at the ends;

FIG. 6 shows a single device from FIG. 1 in a separate three-dimensional illustration having a loop arranged horizontally in relation to the main extension direction and screw connections at the ends;

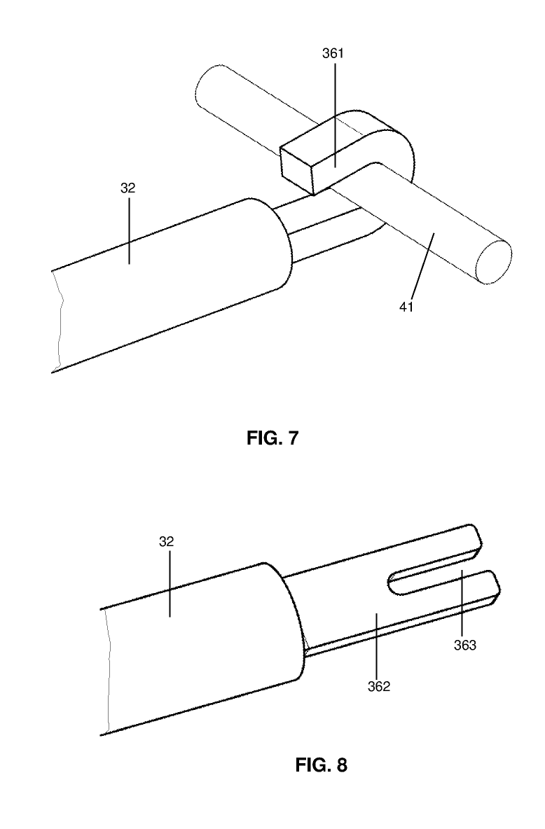

FIG. 7 shows one end of a device having a welding hook formed as a contact region to an adjacent conductor;

FIG. 8 shows one end of a device having a fork formed as a contact region;

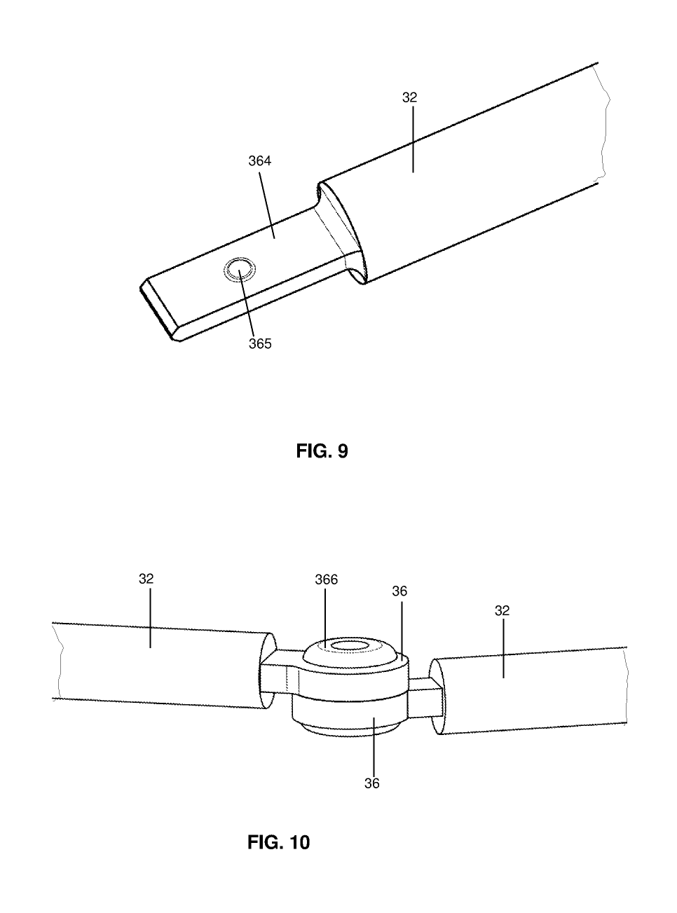

FIG. 9 shows one end of a device having a flattening formed as a contact region;

FIG. 10 shows a contact region for connecting two adjacent devices with eye-shaped flattenings formed in the contact region thereof and a rivet penetrating the loop of the eyes as a fastening means;

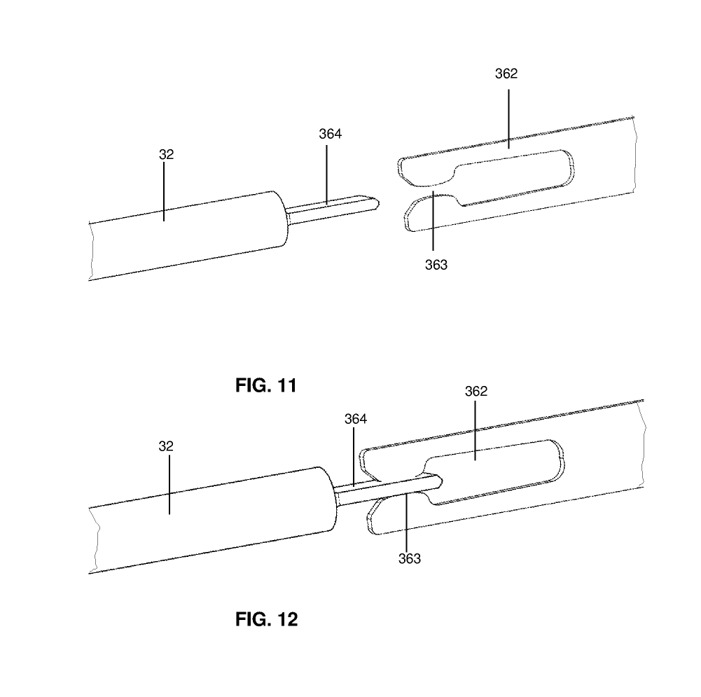

FIG. 11 shows a contact region for connecting two adjacent devices having flattenings formed in the contact region thereof like a tongue and a fork before the assembly;

FIG. 12 shows the contact region according to FIG. 11 after the assembly;

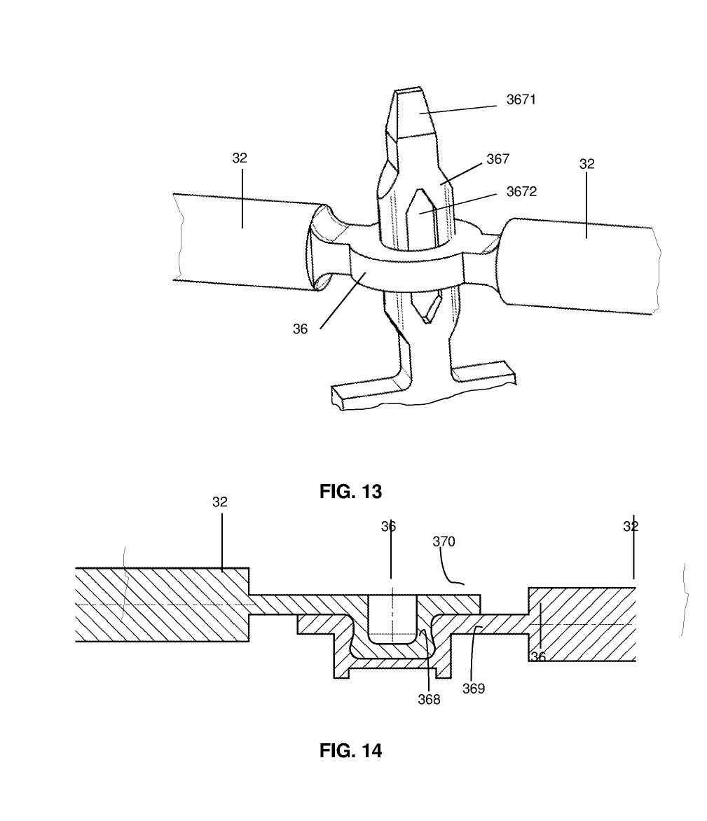

FIG. 13 shows a flattened contact region on a device having a borehole and a press-in dome penetrating it;

FIG. 14 shows a longitudinal section through a contact region of two adjacent devices having depressions formed in the contact regions thereof and press-in parts for producing a clinch or TOX® connection;

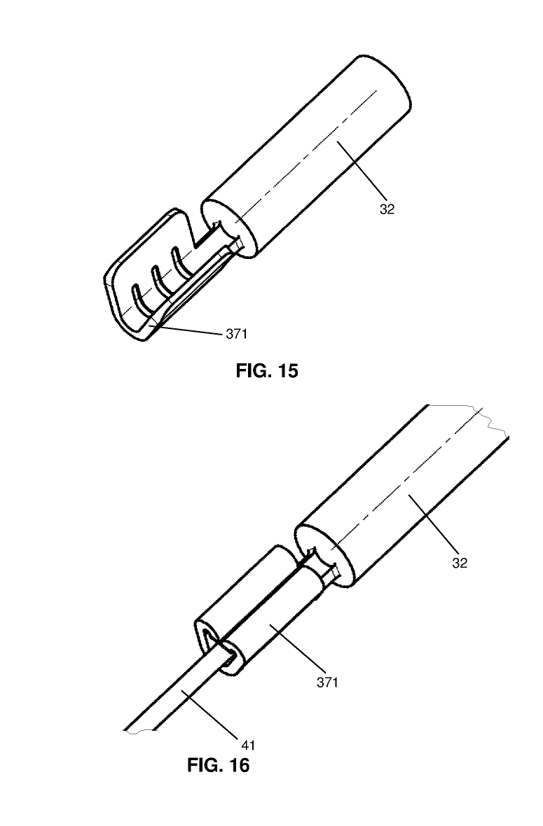

FIG. 15 shows one end of a device having a crimp formation formed as a contact region to an adjacent conductor;

FIG. 16 shows the contact region according to FIG. 15 after production of the crimp connection;

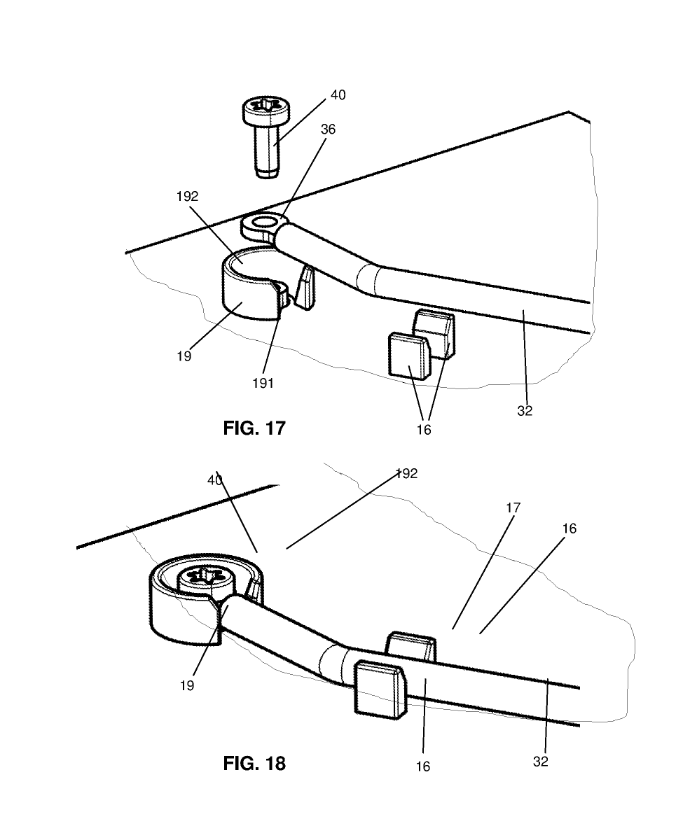

FIG. 17 shows a receptacle formed on a wall of a component for a contact region of a device in the not-yet-connected state;

FIG. 18 shows the receptacle and the contact region in the connected state;

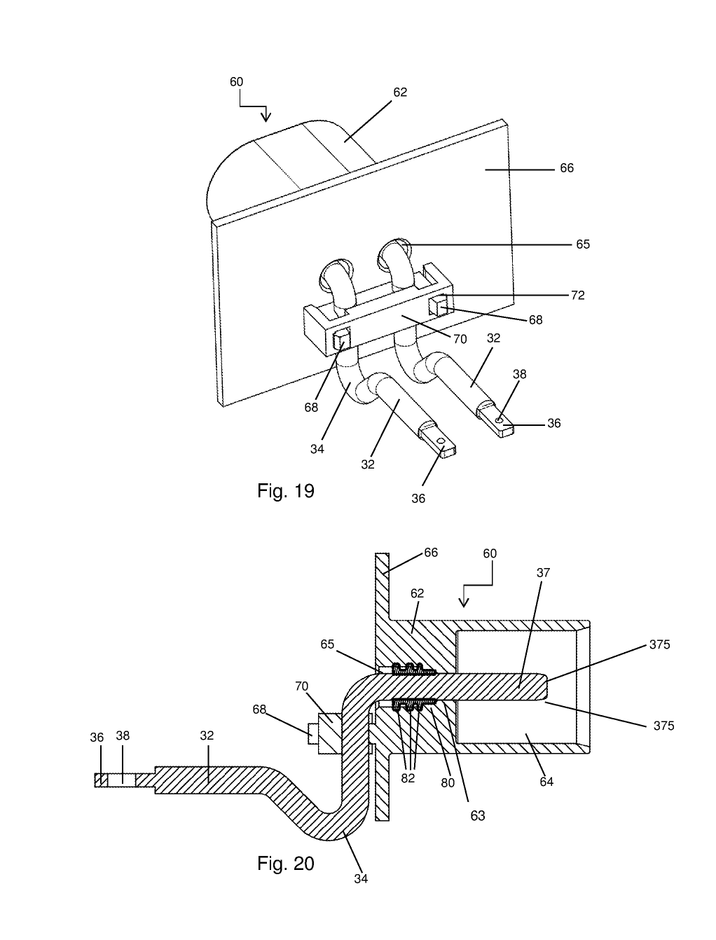

FIG. 19 shows a perspective view of a rear side of a plug;

FIG. 20 shows a longitudinal section through the plug according to FIG. 19 in the region of a wire;

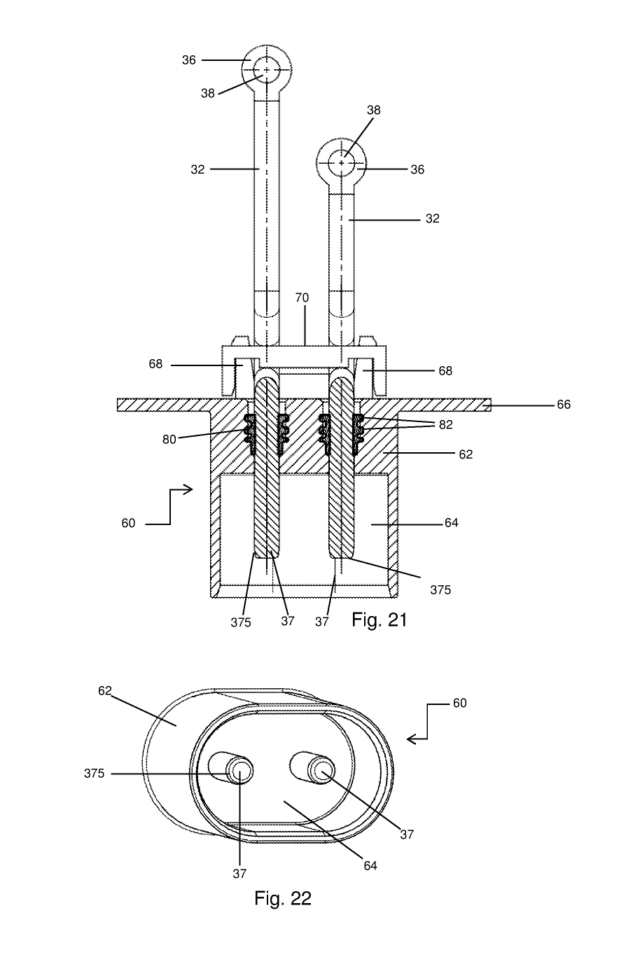

FIG. 21 shows a cross section through the plug according to FIG. 19;

FIG. 22 shows a perspective view of the front side of the plug according to FIG. 19;

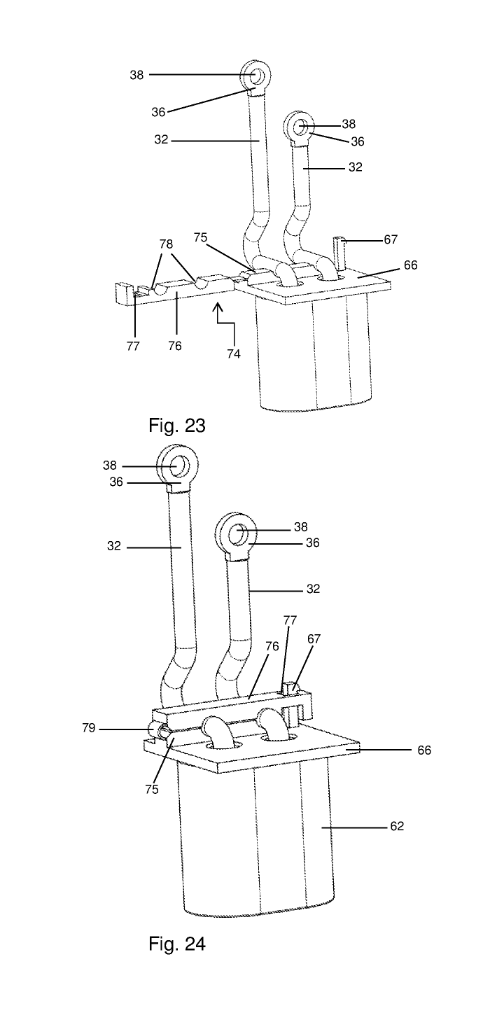

FIG. 23 shows a variant of a plug having a locking element formed on the housing of the plug in the open state;

FIG. 24 shows the plug according to FIG. 23 in the closed state of the locking element;

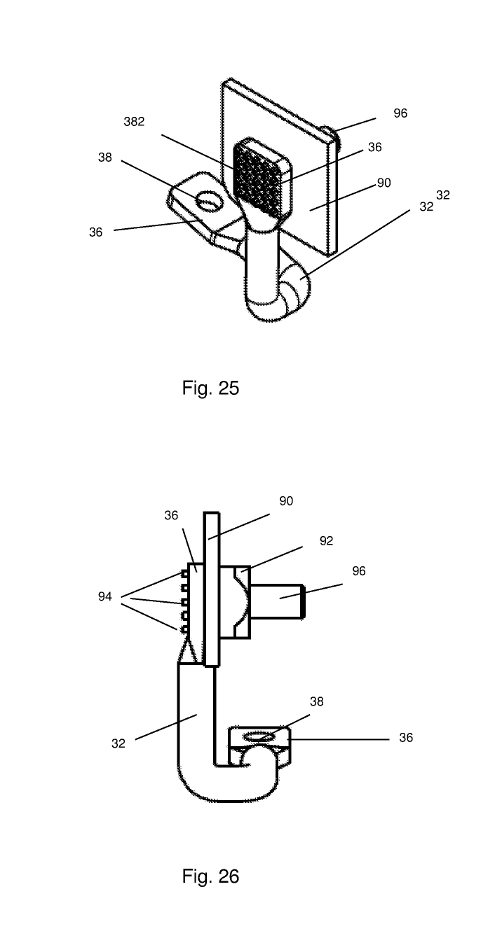

FIG. 25 shows a perspective view of a further contacting device having a contact region prepared for press-in contact pins; and

FIG. 26 shows a side view of the embodiment according to FIG. 25.

An exemplary embodiment of the invention illustrated in FIGS. 1 to 3 shows a housing 10 of an assembly provided with multiple electrical components 20 and/or 22. The housing 10 is provided in the edge region with multiple tabs 12, by means of which the housing 10 is fastenable, for example, in the engine compartment of a vehicle on adjacent components or which are used for attaching a cover (not shown in FIG. 1) for closing the housing 10.

The housing 10 has a trough-shaped receptacle chamber 14, in which ribs 16 extending parallel to one another define multiple guide channels 18, in which signal lines 24 used for the activation of the electrical components 20 and/or 22 extend.

A device according to the invention, which is identified as a whole with 30, is used for connecting the electronic components 20 and/or 22 with a power supply 42 illustrated in FIG. 2. The power supply 42 has a positive pole and a negative pole. The device 30 is composed of multiple wires 32, which preferably have a round cross section. The wires 32 preferably consist of a metal or a metal alloy having a high electrical conductivity, for example, copper.

The wires 32 have, as can be seen in FIG. 2, contact regions 36 at the ends thereof. Depending on the number of the electrical components 20 and/or 22 to be contacted between the ends of the wires 32, further contact regions 36 are also provided between the ends, at which further three-dimensionally bent wires 32 of the same electrical polarization can be connected to supplement the device. Some of the wires 32 are connected to the positive pole of the power supply 42 and are used for the power supply of the electrical components with a corresponding power current. Other wires 32 are connected to the negative pole of the power supply 42 and are used for the return conduction of the power currents.

The wires 32 are brought using multiple bends 34 into a three-dimensional shape for the contacting of at least one electrical component 20 and/or 22, but preferably for the simultaneous contacting of multiple electrical components 20 and/or 22 with one another and/or with the power supply 42. In this case, they preferably follow, as is illustrated in FIG. 3 on the basis of a single wire 32, the X axis, the Y axis, or the Z axis of the housing 10, if necessary also alternating multiple times. However, other bends 34 deviating from a 90° angle are also possible.

The contact regions 36 are formed from the material of the wires 32 by embossing, squeezing, stamping, rolling, or pressing as flat, preferably tab-shaped regions. Suitable forming tools, such as dies, embossing stamps or embossing presses, contour stamping tools, matrices, or the like are preferably used for the forming of the contact regions 36 on the wires 32.

Boreholes 38 are introduced into the contact regions 36, preferably by stamping or drilling, in which, as indicated in the upper region in FIG. 3, sleeves 39 can also be pressed. The boreholes 38 or the sleeves 39, respectively, are used for contacting the wires 32 with the electrical components 20 and/or 22. For this purpose, fastening means 40 are preferably guided through the boreholes 38 or through the sleeves 39, respectively. Torx screws 40 are illustrated by way of example as the fastening means in FIG. 1.

A three-dimensionally bent wire 32 in shown in FIGS. 5 and 6, in the two end regions of which eye-shaped contact regions 36 are formed. The wire 32 additionally has a loop 35 arranged vertically in relation to the main extension direction of the wire 32 in FIG. 5 and arranged horizontally in relation to the main extension direction of the wire 32 in FIG. 6, which is used for compensation of the length of the wire 32 and is preferably elastically or plastically deformable to correct the length of the wire 32. The wire 32 is guided between ribs 16 formed on a wall of the housing 10 or on a plate arranged in the housing 10. For easier pressing in of the wire 32 between the ribs 16, they are preferably provided with insertion bevels 17. The eye-shaped contact regions 36 at the ends of the wire are each accommodated by a receptacle 19 formed on a wall of the housing 10 or on a plate arranged in the housing 10. This receptacle, as illustrated in FIGS. 17 and 18, preferably also has an insertion bevel 192 and in the lower region a base 191 made of an electrically insulating material, so that a contact of the wire 32 which is electrically insulated with respect to the wall of the housing 10 or a plate can be produced. Screws 40 are provided as fastening means in FIGS. 5 and 6 and FIGS. 17 and 18, which penetrate corresponding boreholes in the contact regions 36 and are screwed into a thread in a threaded borehole in the wall of the housing 10 or in the plate.

An end of a wire 32 is provided with a welding hook 361 formed therefrom in FIG. 7, in the U-shaped receptacle of which a conductor 41 is laid and is subsequently welded to the welding hook 361.

A contact region is formed at the end of a wire 32 as a fork 362 having a slot 363 formed therein in FIG. 8. The fork 362 is used with its slot 363 as a welding fork. The slot is used for accommodating a pin-shaped counter contact, which is welded to the fork 362.

The contact region is formed as a flattening 364, which is welded at a spot weld 365 to a counter contact (not shown), in FIG. 9.

A connection of two wires 32 is shown in FIG. 10, which each have a contact region 36 in the form of an eye-shaped flattening with a passage hole at the ends thereof. The contact regions 36 are moved so they are congruent one on top of another and are permanently articulated with one another or optionally also fixedly mechanically and electrically conductively connected to one another by means of a rivet 366 penetrating the passage holes.

One end of a wire 32 is formed as a flattening 364 in FIG. 11. This flattening 364 is used for joining together with a slot 363 in a fork 362, which is provided or formed on a component to be connected or an adjacent wire. In FIG. 12, the contact is produced by inserting the flattening 364, which is provided at the tip with insertion bevels, into the slot 363. In this case, the fork 362 encloses the flattening 364 with a sufficiently strong spring force and clamps it permanently in the slot 363. An additional welded bond can optionally be provided between fork 362 and flattening 364.

An eye-shaped flattened connecting region 36 formed in a wire 32 is provided with a borehole in FIG. 13, which is penetrated by a press-in spike 367 as a counter contact. The press-in spike 367 has insertion bevels 3671 at its upwardly facing tip and is elastically deformable by a cavity 3672 arranged in the connecting region, so that it presses with a strong pressure force against the wall of the borehole after the pressing in.

When reference is made in this application to a “borehole”, a person skilled in the art understands this as any form of an opening, independently of the type of the production, which can also be produced, for example, by stamping or pushing through and independently of the shape, which does not necessarily have to be round.

Two connecting regions 36 arranged at adjacent ends of two wires 32 are formed as flattenings for the attachment of a clinch or TOX® connection in FIG. 14. In this case, the upper flattening is pressed using a press-in part 369 of a stamp, the stamp depression 370 of which remains visible after the joining, in a formfitting manner while forming an undercut in the edge region into a depression 368 of the lower flattening supported by a matrix.

In FIG. 15, a crimp formation 371 is formed at one end of a wire 32, which, after laying an adjacent conductor 41 therein, is pressed fixedly around it by means of a crimping tool (FIG. 16).

The receptacle 19 illustrated in FIGS. 17 and 18 was already described above in conjunction with FIGS. 5 and 6.

A variant of the invention is shown in FIGS. 19 to 24, in which at least one end of at least one wire 32 is formed as a contact 37 of a plug 60. The plug has a housing 62, which forms a large cavity 64 like a bushing on its front side, in the middle of which the two contacts 37 are arranged spaced apart from one another. The contacts 37 have a chamfer 375 at the end thereof facing toward a complementary formed female plug (not shown), which facilitates the joining together of the plugs.

The housing 62 has two small cylindrical receptacles 65 on its rear side, in which the ends of the wires 32 forming the contacts 37 are each pluggable with a plugged-on seal 80. The receptacles 65 are connected via passage boreholes 63 to the cavity 64, the diameter of which is reduced in relation to the receptacles 65 and essentially corresponds to the diameter of the wires 32. The seals 80 enclose the wires 32 while pressing closely against them with a passage arranged in the interior thereof and are applied closely to the wall of the receptacle 65 with multiple sealing lips 82 arranged circumferentially on the outer circumference thereof.

At the sides thereof led out of the rear side of the housing 62, the wires 32 are bent downward by 90°. They are fixed by means of a locking element on the housing 62 in this vertically extending part. The locking element is formed in the exemplary embodiment according to FIGS. 19 to 21 by a catch plate 70, which has two recesses 72, through each of which a pin-shaped catch element 68 protruding from a rear plate 66 of the housing 62 engages and presses the catch plate 70, by means of a springy movable catch hook, against the plate 66 of the housing 62 with clamping of the wires 32 and fixes it thereon.

In the exemplary embodiment according to FIGS. 23 and 24, a catch plate 74 is formed directly on the housing 62. In this case, a lower part 75 of the catch plate 74 is formed directly on the rear side of the plate 66. The lower part 75 has two semicircular grooves for accommodating the wires 32. The lower part 75 is connected at one end by means of a film hinge 79 to an upper part, which also has two semicircular grooves 78, which tightly enclose the wires 32, jointly with the grooves on the lower part, after closing of the catch plate 74. For the closing, the upper part is provided at its end opposite to the film hinge 79 with a recess 77, through which a pin-shaped catch element 67 arranged on the rear side of the plate 66 engages with a springy movable barb and fixedly holds together the two parts 75 and 76 of the catch plate 74 in the closed position.

The rear sides of the wires 32 facing away from the plug 60 subsequently extend parallel to the contacts 37 again adjoining a bend 34. At the ends thereof, they are connected via contact regions 36 having boreholes 38 with adjacent wires 32 or with electrical components 20 and/or 22.

A further exemplary embodiment of the invention is shown in FIGS. 25 and 26, in which a wire 32, which is round in cross section and is already pre-bent into a shape required for a contact, is integrally formed at one end with an eye-shaped flattened contact region 36 corresponding to FIG. 2, having a borehole 38 arranged therein, preferably by forming. The other end of the wire 32 is provided with a contact region 36, which is formed as square or rectangular in the exemplary embodiment shown and is flattened by forming, and in which a plurality of boreholes 382 arranged in a regular hole grid are formed. In the exemplary embodiment shown, these are twenty-five boreholes 382 arranged in a uniform, square hole grid. Other arrangements having square hole grids, for example, having nine, sixteen, or thirty-six boreholes 382 or also non-square, for example, rectangular, hexagonal, or octagonal hole grids can also be used.

The boreholes 382 are used for the formfitting engagement of a preferably equal number of contact pins 94, which are arranged on a contact component 92. The contact component has, on its right side in FIGS. 25 and 26, a contact dome 96 for attaching an adjacent component or an electrical conductor or a connecting element. The contact pins 94 are optionally used in the same time in the exemplary embodiment shown for contacting and fastening a plate 90, which is arranged between the contact component 92 and the flattened contact region 36. The contact pins are preferably pressed into the boreholes 382 and thus form a permanent secure connection between the contact component 92 and the flattened contact region 36 of the wire 32.

In FIG. 4, power rails 50, which have previously been used and are formed from flat plates, and which have been brought by stamping and bending into the desired shape, are shown to illustrate the previous prior art. A relatively large amount of waste arises during the stamping of such power rails. The bending into a three-dimensional shape is only possible to a limited extent for such plates.

The wires 32 can preferably be provided with an insulating coating outside the contact regions 36, 361, 362, 363, 364, 365, 368, 370, 371, 37 after the bending into the desired 3D contour. This can be performed, for example, by immersion in an insulating lacquer while covering the contact regions 36, 361, 362, 363, 364, 365, 368, 370, 371, 37.

[symbol]

List of reference signs

| | |
|---|---|
| 10 | housing |
| 12 | tab |
| 14 | receptacle chamber |
| 16 | rib |
| 17 | insertion bevel |
| 18 | guide channel |
| 19 | receptacle |
| 191 | base |
| 192 | insertion bevel |
| 20 | (electrical) component |
| 22 | (electrical) component |
| 24 | signal line |
| 30 | device |
| 32 | wire |
| 34 | bend |
| 35 | loop |
| 36 | contact region |
| 361 | welding hook |
| 362 | fork |
| 363 | slot |
| 364 | flattening |
| 365 | spot weld |
| 366 | rivet |
| 367 | press-in spike |
| 3671 | insertion bevel |
| 3672 | cavity |
| 368 | depression |
| 369 | press-in part (clinch) |
| 370 | stamp depression |
| 371 | crimp formation |
| 37 | contact |
| 375 | phase |
| 38 | borehole |
| 382 | boreholes (hole grid) |
| 39 | sleeve |
| 40 | fastening means (screw) |
| 41 | conductor |
| 42 | power supply |
| 50 | power rail |
| 60 | plug |
| 62 | housing (of 60) |
| 64 | cavity (bushing, at 62) |
| 65 | receptacle (at 62) |
| 66 | plate (at 62) |
| 67 | catch element (at 62) |
| 68 | catch element (at 62) |
| 70 | catch plate |
| 72 | recess |
| 74 | catch plate (at 62) |
| 75 | lower part (of 74) |
| 76 | upper part (of 74) |
| 77 | recess |
| 78 | groove |
| 79 | film hinge |
| 80 | seal element |
| 82 | sealing lip |
| 90 | plate |
| 92 | contact component |
| 94 | contact pins |
| 96 | contact dome |
| X | X axis |
| Y | Y axis |
| Z | Z axis |
| + | positive pole |
| − | negative pole |

1. A device for connecting electrical components with a power supply, wherein the device is formed by at least one three-dimensionally bent wire, which has a round cross section and in which contact regions are formed at least at its ends characterized in that at least one further contact region is formed into the wire at least one further point located between the ends of the wire.

2. (canceled)

3. (canceled)

4. The device as claimed in claim 1, characterized in that the contact regions are formed as flat embossed regions of the wire.

5. The device as claimed in claim 1, characterized in that the contact regions are formed as a connecting region to an adjacent three-dimensionally bent wire.

6. The device as claimed in claim 1, characterized in that at least one borehole and/or at least one depression and/or at least one welding hook and/or at least one fork and/or at least one flattening and/or at least one spot weld and/or at least one crimp formation is formed in at least one of the contact regions.

7. The device as claimed in claim 6, characterized in that the borehole or depression is used to accommodate at least one fastening means.

8. The device as claimed in claim 6, characterized in that at least one rivet or one press-in spike or one press-in part or one sleeve can be pressed or at least one screw can be screwed into the borehole or depression.

9. The device as claimed in claim 1, characterized in that the wire consists of a metal or a metal alloy having high electrical conductivity.

10. The device as claimed in claim 1, characterized in that the contact regions are formed in the wire by pressing, squeezing, and/or stamping and the wire is brought into its three-dimensional shape by means of a bending device.

11. The device as claimed in claim 1, characterized in that at least one loop is formed in the at least one three-dimensionally bent wire.

12. The device as claimed in claim 1, characterized in that the contact regions are formed at least at one end of the wire as the contact of a plug.

13. The device as claimed in claim 12, characterized in that the contacts are insertable, provided with a seal element, into a receptacle of the plug.

14. The device as claimed in claim 12, characterized in that the end of the wire formed as the contact is fixable by means of a locking element on a housing of the plug.

15. The device as claimed in claim 14, characterized in that the locking element is at least partially formed on the housing.

16. The device as claimed in claim 1, characterized in that the at least one three-dimensionally bent wire is provided with an insulating coating outside the contact regions.

17. The device as claimed in claim 14, characterized in that the insulating coating is formed by immersion in an insulating lacquer while covering the contact regions.

18. The device as claimed in claim 3, characterized in that the contact regions are formed as a connecting region to an adjacent three-dimensionally bent wire.

19. The device as claimed in claim 3, characterized in that at least one borehole and/or at least one depression and/or at least one welding hook and/or at least one fork and/or at least one flattening and/or at least one spot weld and/or at least one crimp formation is formed in at least one of the contact regions.

20. The device as claimed in claim 7, characterized in that at least one rivet or one press-in spike or one press-in part or one sleeve can be pressed or at least one screw can be screwed into the borehole or depression.

21. The device as claimed in claim 13, characterized in that the end of the wire formed as the contact is fixable by means of a locking element on a housing of the plug.

22. The device as claimed in claim 3, characterized in that the at least one three-dimensionally bent wire is provided with an insulating coating outside the contact regions.
